(19) United States
(12) Patent Application Publication
(10) Pub. No.: US 2015/0303336 A1
(43) Pub. Date: Oct. 22, 2015

(54) WEATHERABLE COMPOSITE FOR FLEXIBLE THIN FILM PHOTOVOLTAIC AND LIGHT EMITTING DIODE DEVICES

(71) Applicant: Arkema Inc., King of Prussia, PA (US)

(72) Inventors: Amy A. Lefebvre, Pottstown, PA (US); Gregory S. O'Brien, Downingtown, PA (US); Walter KOSAR, Pottstown, PA (US); Kurt A. WOOD, Abington, PA (US)

(21) Appl. No.: 14/376,859

(22) PCT Filed: Feb. 7, 2013
(86) PCT No.: PCT/US13/25029

§ 371 Date: Aug. 6, 2014

Related U.S. Application Data
(60) Provisional application No. 61/597,431, filed on Feb. 10, 2012.

(51) Int. Cl. H01L 31/048; H01L 31/032; H01L 31/049

(52) U.S. Cl. CPC H01L 31/048; H01L 31/049; H01L 31/0322

(57) ABSTRACT

The invention provides a weatherable composite including a moisture barrier system having a moisture vapor transmission rate at or below 1×10⁻² g/m²/day, at least one weatherable layer or coating, and a substrate that is disposed between the moisture barrier system and the weatherable layer or coating. The weatherable composite may be adhered to one or both sides (e.g., front and back) of a photovoltaic thin-film cell or organic light emitting diode such that the weatherable layer(s) or coating side(s) of the weatherable composite is exposed to the environment. The weatherable composite protects the device from both moisture and UV exposure.

### FIELD OF THE INVENTION

The invention relates to substrates having a low moisture vapor transmission rate coated or provided with at least one weatherable layer or coating to produce a weatherable composite with a low moisture vapor transmission rate. One specific use of the composite is as a protective layer on the outside of a photovoltaic module for capturing and using solar radiation. The weatherable layer or coating portion of the composite is exposed to the environment and provides chemical resistance, electrical insulation, and weathering protection.

### BACKGROUND OF THE INVENTION

Photovoltaic modules may include an outer (front) glazing material, solar cells, a backsheet, and are generally encapsulated in a clear packaging (encapsulant) for protection. The solar cells are made of materials known for use in solar collectors, including, but not limited to, silicon, cadmium indium selenide (CIS), cadmium indium gallium selenide (CIGS), quantum dots, and organic molecules, either polymeric or small molecules.

Light emitting diodes (LEDs) are known and are used in many applications, such as in displays and status indicators. LEDs may be formed from organic and/or inorganic materials. Organic LEDs (OLEDs) typically include an organic material for the light emitting layer and may provide large area surface emitting light sources.

The front and/or back of photovoltaic or OLED devices are typically exposed to the environment. When certain substrates are used in these devices, such as polyethylene terephthalate (PET) or polyethylene naphthalate (PEN), they are known to be quite sensitive to UV degradation and can degrade relatively rapidly when exposed to UV radiation. Thus, even though certain polymers, such as PET, provide good water vapor resistance and are relatively low cost, they may be susceptible to degradation from exposure to environmental influences, such as UV radiation, IR radiation, and thermal effects. Due to such degradation, the lifetimes when PET is used without a protective layer are much shorter than the expected lifetime of the devices, e.g., 20+ year lifetime for solar panels on the market today. Thus, there is a need to protect these devices and the PET layers utilized from UV radiation.

Additionally, some photovoltaic and OLED devices are especially susceptible to moisture degredation. For example, some photovoltaics will stop working completely if exposed to too much moisture. One example is CIGS solar cells that after less than 1000 hours in damp heat (e.g., about 85° C. and 85% relative humidity (RH)) have in some tests shown a loss of greater than 50% of the original cell efficiency. Accordingly, there is a need to also protect these devices from exposure to moisture in the environment.

### SUMMARY OF THE INVENTION

Aspects of the present invention include weatherable composites that can be used to protect devices, such as photovoltaic modules and OLEDs, from UV and moisture exposure, methods of making the same, and the devices obtainable therefrom.

According to an embodiment of the present invention, a weatherable composite includes a moisture barrier system having a moisture vapor transmission rate at or below 1×10⁻² g/m²/day (e.g., at about 38° C. and 85% RH), at least one weatherable layer or coating, and a substrate that is disposed between the moisture barrier system and the at least one weatherable layer or coating. The weatherable composite may be adhered to one or both sides (e.g., front and back) of a photovoltaic thin-film cell or organic light emitting diode with an encapsulant such that the weatherable layer(s) or coating side(s) of the weatherable composite is/are exposed to the environment.

According to another embodiment of the present invention, a weatherable composite includes a moisture barrier layer or layers that comprise alternating organic and inorganic layers, an atomic layer deposition (ALD) inorganic barrier layer, a polysilazane barrier layer, or other technology known in the art to produce high moisture barriers. The moisture barrier may have a moisture vapor transmission rate at or below 1×10⁻² g/m²/day at 38° C. and 85% RH. The weatherable composite includes at least one weatherable layer or coating comprising polyvinylidene fluoride preferably providing UV protection to the substrate and all layers beneath the at least one weatherable layer, and a substrate comprising polyethylene terephthalate, polyethylene napthalate, or polybutylene terephthalate. The substrate is disposed between the moisture barrier layer or layers and the at least one weatherable layer or coating. For example, a photovoltaic cell may be adhered to two weatherable composites with an encapsulant such that one weatherable composite is transparent and the second weatherable composite is translucent or opaque, wherein this second weatherable composite is a PVDF based coating containing one or more pigments, such as TiO₂. Typical encapsulants include, but are not limited to, ethyl vinyl acetate, a polyolefin, a functional polyolefin, a ionomer, a silicone, a grafted polyolefin-polyamide copolymer, and polyvinyl butryl.

According to another embodiment of the present invention, a method for forming a weatherable composite includes applying a moisture barrier system having a moisture vapor transmission rate at or below 1×10⁻² g/m²/day to a substrate, and applying at least one weatherable layer or coating to the substrate. The weatherable composite may then be applied, adhered, or laminated to a photovoltaic or OLED device on one or both sides to protect the device from the environment.

### BRIEF DESCRIPTION OF THE DRAWINGS

The invention may be further understood with reference to the drawings, in which:

FIG. 1 depicts a weatherable composite according to an embodiment of the present invention comprising a coating, a substrate, and a moisture barrier system;

FIG. 2 depicts the embodiment shown in FIG. 1 with a representation of a suitable moisture barrier system; and

FIG. 3 depicts an embodiment of the present invention where a photovoltaic module is sandwiched between two weatherable composites of the type depicted in FIG. 1.

### DETAILED DESCRIPTION OF THE INVENTION

Aspects of the present invention include weatherable composites having a moisture barrier system with a given moisture vapor transmission rate, methods of making the same, and devices incorporating the weatherable composites. In particular, some embodiments of the present invention include a moisture barrier system, for example, having alternating layers of organic and inorganic films, deposited or applied onto a substrate, such as PET or PEN substrates, and at least one weatherable layer or coating applied to the opposite side of the substrate preferably providing UV protection to layers beneath it.

As used herein, “weatherable” is a measurable characteristic known to one skilled in the art that shows how well a material or product performs during exposure to outdoor weather conditions, such as ultraviolet light, rain, snow, high and low temperatures, humidity, environmental pollution, acidity in the air, and the like. A weatherable material desirably exhibits little or no adverse effects (e.g., discoloration, disintegration, wear) due to prolonged exposure to the environment. Thus, weatherable devices, such as photovoltaics, preferably survive in an outdoor environment for at least their intended life span (e.g., 20+ years).

The weatherable composites described herein may be used on one or both sides (e.g., front and back) of a device, such as a photovoltaic (PV) module (e.g., photovoltaic thin-film cell) or organic light emitting diode in order to protect the device from both UV and moisture exposure.

As used herein, “photovoltaic module” is intended to encompass any suitable construction of photovoltaics, such as photovoltaic cell circuits sealed in an environmentally protective laminate. Photovoltaic modules may be combined to form photovoltaic panels that are pre-wired, field-installable units. Photovoltaic modules and photovoltaic panels may be used interchangeably. A photovoltaic array may include the complete power-generating unit, consisting of any number of PV modules and panels. The photovoltaic or solar cell includes any suitable device that converts light energy directly into electricity. The photovoltaic thin-film cell is intended to include devices using thin-film technology known in the art and having thin and flexible configurations, such as copper-indium-gallium-selinide (CIGS), cadmium telluride (CdTe), organic photovoltaic (OPV) thin film, etc.

As used herein and in the claims, the terms “comprising” and “including” are inclusive or open-ended and do not exclude additional unrecited elements, compositional components, or method steps. Accordingly, the terms “comprising” and “including” encompass the more restrictive terms “consisting essentially of” and “consisting of.” Unless specified otherwise, all values provided herein include up to and including the endpoints given.

According to an embodiment of the present invention, a weatherable composite includes a moisture barrier system having a moisture vapor transmission rate at or below 1×10⁻² g/m²/day, at least one weatherable layer or coating, and a substrate that is disposed between the moisture barrier system and the at least one weatherable layer or coating.

Moisture Barrier System

The weatherable composite includes a moisture barrier system having a moisture vapor transmission rate (MVTR) at or below 1×10⁻² g/m²/day (e.g., at about 38° C. and 85% RH). The moisture vapor transmission rate (MVTR) is a measure (typically expressed as grams or milligrams of water per cubic meter per day) that indicates the degree of moisture transmission or the passage of water vapor through a material. Thus, a lower MVTR indicates a higher moisture barrier or hindrance of water migration through a material. The MVTR may be measured at a given temperature and humidity, for example, at about 38° C. and 85% RH. The MVTR may be measured in accordance with ASTM F1249-06 (2011) Standard Test Method for Water Vapor Transmission Rate Through Plastic Film and Sheeting Using a Modulated Infrared Sensor. In one embodiment of the present invention, the moisture barrier system has a moisture vapor transmission rate (MVTR) at or below 1×10⁻³ g/m²/day, which may be preferable to protect organic photovoltaics, for example. In another example, the MVTR is below 1×10⁻⁴, which may be preferable to protect CIGS PV cells over a long lifetime. In another embodiment, the moisture barrier system has a MVTR at or below 1×10⁻⁵ g/m²/day, which may be preferable to protect flexible OLEDs, for example. In an exemplary embodiment, the moisture barrier system has an MVTR at or below 1×10⁻⁶ g/m²/day.

Although some materials, such as PET substrates, are known to exhibit good moisture barrier properties, these materials may not provide sufficient moisture protection for the applications and devices envisioned in the present invention. For example, PET with a 1 mil thickness may have an MVTR of about 25 g/m²/day. Thus, while this MVTR may provide sufficient moisture barrier protection for some devices, the MVTR is not sufficiently low to protect devices with high sensitivity to moisture exposure (e.g., CIGS and organic photovoltaics (OPV)). In short, some references describe a substrate such as PET as a barrier layer, but this type of barrier layer alone would not impede the moisture transmission sufficiently to reach the desired moisture vapor transmission rates of the present invention.

The moisture barrier system may comprise any suitable barrier technology necessary to provide for vapor transmission at the desired rates. Suitable barrier technology may be selected, for example, based on certain material(s), varying numbers of layer(s), and varying thickness(es). For instance, the material or materials may be selected based on desired permeability rates. Also, as would be recognized by one skilled in the art, the transmission rates may be directly proportional to thickness and/or the number of layers. For example, a thicker material may provide for a lower MVTR.

In one embodiment of the present invention, the moisture barrier system comprises one or more layers. For example, the moisture barrier layer or layers may comprise alternating organic and inorganic layers, an atomic layer deposition (ALD) inorganic barrier layer, a polysilazane barrier layer, or other technology known in the art to produce high moisture barriers. Preferably, the moisture barrier is selected by one of ordinary skill in the art to provide the desired MVTR, e.g., a moisture vapor transmission rate at or below 1×10^{×2} g/m²/day at 38° C. and 85% RH. Suitable moisture barriers are described, for example, in U.S. Pat. No. 6,522,067, U.S. Publication No. 2009/0081842, International Publication No. WO 2011/103341, and U.S. Publication No. 2010/0166977, each of which is incorporated herein by reference in its entirety for all purposes. For example, a moisture barrier coating based on polysilazanes is described in U.S. Publication No. 2010/0166977.

In one embodiment, the moisture barrier system comprises alternating layers of organic and inorganic films. The alternating organic-inorganic layers may create a tortuous path for the moisture, which reduces the MVTR value. Depending on the application, it may be useful for the moisture barrier system to be a flexible, multi-layer material (e.g., having more than one organic and more than one inorganic layer). The organic layers may comprise a polymer, for example. Illustrative examples of suitable polymer layers may include, but are not limited to, polyacrylates (e.g., polymethylmethacrylate), polyesters (e.g., polyethylene terephthalate, polyethylene naphthalate), polyamides, polyimides, polycarbonates and the like. In an exemplary embodiment, the organic layers comprise a polymer selected from the group consisting of polyacrylates, polyesters, polyimides, and polycarbonates. For example, the organic layers may be selected from the group consisting of polyethylene terephthalate (PET), polyethylene naphthalate (PEN), polyvinylidene fluoride (PVDF), polymethyl methacrylate (PMMA), and combinations thereof.

In one embodiment, each of the organic layers in the barrier system is transparent. In still another embodiment, at least one of the surfaces of at least one of the organic layers in the barrier system is plasma-treated. One or more of the organic layers in the barrier system may have been formed by depositing a liquid precursor of the organic layer onto a surface of a substrate, forming a liquid film. The liquid film may then be converted to a polymer by, for example, exposing the liquid film to a source of ultraviolet light effective to cure or polymerize the liquid precursor (where such liquid precursor is UV-curable), by exposing the liquid film to a LED or e-beam, or by exposing the liquid film to heat.

The inorganic layers may comprise any suitable materials that exhibit moisture barrier properties, such as metal oxides or transition metal oxides. Other suitable inorganic materials include, but are not limited to, metal nitrides, metal carbides, metal oxynitrides, metal oxyborides and the like and combinations thereof. In one embodiment, the inorganic layer comprises, for example, a metal oxide or transition metal oxide in substantially pure form or as a mixed oxide. As used herein, “substantially pure” is intended to encompass a layer consisting essentially of the metal oxide or transition metal oxide (e.g., along with some common impurities) or consisting of only the metal oxide or transition metal oxide. The “mixed oxide” may include a mixture or composite of at least two metal or transitional metal oxides. The mixed oxide may be a composite oxide, homogenous oxide, heterogeneous oxide, or the like. Additionally, the oxides may be doped or undoped metal oxides.

The inorganic layers may comprise a metal oxide or transition metal oxide (MOₓ) including, but not limited to, silicon oxides (SiOₓ), tin oxides (SnOₓ), aluminum oxides (AlₓO_{y}), zinc oxides (ZnOₓ), titanium oxides, indium oxides, indium tin oxides, tantalum oxides, zirconium oxides, niobium oxides, silicon aluminum oxides, etc. The inorganic layers may also comprise oxynitride thin films, such as silicon oxynitride (SiOₓN_{y}) or aluminum oxynitride (AlOₓN_{y}), for example. In an exemplary embodiment, the metal oxide is selected from the group consisting of silicon oxides, tin oxides, aluminum oxides, zinc oxides, and mixtures thereof.

In one embodiment, each of the inorganic layers in the barrier system is transparent. In another embodiment, at least one of the inorganic layers in the barrier system is transparent.

The alternating inorganic-organic layers may be formed in any suitable way and may contain the same or different materials. For example, the inorganic layers may be deposited onto the organic layers, for example, using chemical vapor deposition. The barrier system may also be obtained from a commercial source, such as Barix™ Barrier Film obtainable from Vitex Systems with offices in San Jose, Calif.

Barrier systems useful in the present invention are described, for example, in U.S. Pat. Nos. 4,842,893; 4,954,371; and 5,260,095 as well as U.S. Publication No. 2003/0203210, each of which is incorporated herein by reference in its entirety for all purposes.

The alternating inorganic-organic layers may be of any suitable thickness. For example, the thicknesses of the inorganic layers may be on the order of less than 20 nm, less than 10 nm, or less than 5 nm, and the thicknesses of the organic layers may be on the order of less than 10 mil, less than 5 mil, less than 3 mil, or less than 1 mil. The layers may be the same in thickness or different thicknesses. The alternating inorganic-organic layers may also have any suitable number of layers, such as two or greater layers of each organic and inorganic layer (i.e., four total layers—organic/inorganic/organic/inorganic) or four or greater layers of each organic and inorganic layer (i.e., eight total layers), for example.

Accordingly, the moisture barrier system is a selection of any suitable material(s), number of layer(s), and varying thickness(es) necessary to provide for vapor transmission at the desired rates, e.g., a MVTR at or below 1×10⁻² g/m²/day. In one embodiment, the moisture barrier system is based on barrier technology that is thin, flexible, and transparent.

Weatherable Coating or Layer

The weatherable composite includes at least one weatherable coating or layer. The at least one weatherable coating or layer may include a single layer or multiple layers. In one embodiment, the weatherable coating or layer includes two or more layers (e.g., a multilayer system).

The at least one weatherable coating or layer comprises at least one polymer, is such as fluoropolymers, acrylics, silicone-acrylics, silicone-polyesters, etc. The term “acrylic” is intended to encompass acrylic polymers (homopolymers, copolymers, or terpolymers) derived from acrylic acid monomers, such as acrylic acid and methacrylic acid, for example, and derivatives thereof, such as esters. These monomers may include methacrylate and acrylate monomers, but are not limited to, methyl acrylate, ethyl acrylate and ethyl methacrylate, butyl acrylate and butyl methacrylate, iso-octyl methacrylate and acrylate, lauryl acrylate and lauryl methacrylate, stearyl acrylate and stearyl methacrylate, isobornyl acrylate and methacrylate, methoxy ethyl acrylate and methacrylate, and 2-ethoxy ethyl acrylate and methacrylate. In one embodiment, the weatherable coating or layer may be selected from the group consisting of fluoropolymers, acrylics, silicone-acrylics, silicone-polyesters, and mixtures thereof.

The layers may be the same or different. In one embodiment, the weatherable coating or layer may include multiple layers with different compositions. In one embodiment, the coating could be two layers formed independently, for example. When there are two or more layers, the layers should preferably contain compatible polymers or coatings that will chemically bond to each other. In one embodiment, the substrate may be coated with one layer of acrylic polymer and then another layer of a fluoropolymer acrylic blend, for example, such as PVDF-PMMA or an AMF hybrid as described below.

In one embodiment, the weatherable composite includes at least one weatherable coating or layer comprising at least one fluoropolymer. The term fluoropolymer denotes any polymer that has in its chain at least one monomer chosen from compounds containing a vinyl group capable of opening in order to be polymerized and that contains, directly attached to this vinyl group, at least one fluorine atom, at least one fluoroalkyl group, or at least one fluoroalkoxy group. Examples of fluoromonomers include, but are not limited to, vinyl fluoride; vinylidene fluoride (VDF); trifluoroethylene (VF3); chlorotrifluoroethylene (CTFE); 1,2-difluoroethylene; tetrafluoro ethylene (TFE); hexafiuoropropylene (HFP); perfluoro(alkyl vinyl) ethers, such as perfluoro(methyl vinyl) ether (PMVE), perfluoro(ethyl vinyl) ether (PEVE) and perfluoro(propyl vinyl) ether (PPVE); perfluoro(1,3-dioxole); perfluoro(2,2-dimethyl-1,3-dioxole) (PDD). Preferred fluoropolymers are the homopolymers and copolymers of vinylidene fluoride (VDF).

The fluoropolymer compositions may also be formulated with any suitable solvent and mixtures thereof known in the art, including organic solvents. For example, suitable solvents may include aromatic hydrocarbons, such as toluene and xylene; esters, such as ethyl acetate, butyl acetate, and methoxypropylacetate; ketones, such as acetone, cyclohexanone and methyl isobutyl ketone; lactones, such as gamma-butyrolactone; amides, such as N,N-dimethyl acetamide; glycol ethers, such as diethylene glycol butyl ether, propylene glycol methyl ether, ethylene glycol butyl ether and dipropylene glycol methyl ether, and their esters; and N-methyl pyrrolidone.

Particularly suitable fluoropolymers include those that respond to latent solvents (a latent solvent being one that does not dissolve or substantially swell the fluoropolymer resin at room temperature, but will solvate the fluoropolymer resin at elevated temperatures). As used herein, “hydrophobic” latent solvent is intended to encompass a solvent which has a solubility in water of less than 10% by weight at 25° C.

Each fluoropolymer layer composition of the invention may be a homopolymer, a copolymer, a terpolymer or a blend of a fluoropolymer homopolymer or copolymer with one or more other polymers that are compatible with the fluoropolymer (co)polymer. For example, fluoropolymer copolymers and terpolymers of the invention may include those in which vinylidene fluoride units comprise greater than 40 percent of the total weight of all the monomer units in the polymer, and more preferably, comprise greater than 70 percent of the total weight of the units. Copolymers, terpolymers and higher polymers of vinylidene fluoride may be made by reacting vinylidene fluoride with one or more monomers from the group consisting of vinyl fluoride, trifluoroethene, tetrafluoroethene, one or more of partly or fully fluorinated alpha-olefins, such as 3,3,3-trifluoro-1-propene, 1,2,3,3,3-pentafluoropropene, 3,3,3,4,4-pentafluoro-1-butene, and hexafluoropropene, the partly fluorinated olefin hexafluoroisobutylene, perfluorinated vinyl ethers, such as perfluoromethyl vinyl ether, perfluoroethyl vinyl ether, perfluoro-n-propyl vinyl ether, and perfluoro-2-propoxypropyl vinyl ether, fluorinated dioxoles, such as perfluoro(1,3-dioxole) and perfluoro(2,2-dimethyl-1,3-dioxole), allylic, partly fluorinated allylic, or fluorinated allylic monomers, such as 2-hydroxyethyl allyl ether or 3-allyloxypropanediol, and ethene or propene. Preferred copolymers or terpolymers are formed with vinyl fluoride, trifluoroethene, tetrafluoroethene (TFE), chlorotrifluoroethylene (CTFE) and hexafluoropropene (HFP).

The fluoropolymer layer could also be a blend of a PVDF polymer with a compatible polymer, such as, but not limited to, an acrylic polymer or copolymer, like polymethyl methacrylate (PMMA) or copolymers of MMA with acrylic monomers, such as ethylacrylate or butylacrylate. For example, PVDF and PMMA can be melt blended to form a homogeneous blend. A preferred embodiment is a blend of 50-90 weight percent of PVDF and 10-50 weight percent of polymethyl methacrylate or a polymethylmethacrylate copolymer, with the PMMA copolymer containing at least 70 weight percent of methulmethacrylate monomer groups, and preferable at least 80 weight percent. Even more preferably at least 90 weight percent. The acrylic polymer may be functionalized or non-functionalized, and may be a blend of different acrylic polymers. Useful reactive functional groups include, but are not limited to carboxylate, amine, carboxylic acid, anhydride, melamine, sulfonic acid, aziridine, isocyanate, hydroxyl, and epoxy. Other functional groups may also be useful on the acrylic polymer, such as acrylamide, carbamate, ureido and alkoxysilane functionalities. In one embodiment, the acrylic polymer is non-functionalized. The PVDF or some part of it may also be functionalized. It is also envisioned that the co-resin (e.g., acrylic) and/or the PVDF can be cross-linked to enhance barrier properties. The acrylic resin, functionalized or non-functionalized, may also be part of an intimate blend with the fluoropolymer, such as in an acrylic modified fluoropolymer formed from an acrylic polymer being produced in the presence of a fluoropolymer seed.

In a further embodiment of the invention, fluoropolymer compositions may be used which are aqueous dispersions of the polymers, and which contain little or no organic solvent (less than about 20 weight percent on total formulation weight, preferably less than about 10 weight percent). Examples of such aqueous compositions include fluoropolymer/acrylic hybrid dispersions, also known as acrylic-modified fluoropolymer (“AMF”) dispersions. AMF dispersions are formed by swelling a fluoropolymer seed dispersion with one or more acrylic monomers and then polymerizing the acrylic monomers. The AMF dispersions can be of one of several types. In one type, the particles in the aqueous dispersion have a substantially homogeneous or “interpenetrating network” distribution of the fluoropolymer and acrylic polymers within the particle. In another type, the distribution of the component resins within the aqueous dispersion particle is substantially heterogenous; for instance, the distribution may be of a so-called “core-shell” or “raspberry” morphology, or some other morphology, as is well known in the art for aqueous multistage polymer dispersions. Homogeneous distributions are often preferred because of advantages in outdoor weatherability. It is also envisioned that the co-resin (e.g., acrylic) and/or the PVDF may be cross-linked to enhance barrier properties. It is also envisioned that the AMF can be produced with at least one functional comonomer that allows the final coating to be cross-linked increasing its hardness and thermal resistance.

In one embodiment, the fluoropolymer coating is formed from a PVDF solution, a PVDF latent solvent dispersion, or an aqueous dispersion utilizing AMF technology, such as products sold under the KYNAR AQUATEC® trademark, available from Arkema with offices in King of Prussia, Pa.

In another embodiment, the fluoropolymer coating comprises fluoroethylene vinyl ether resins (FEVE). The fluoroethylene vinyl ether resins may include solvent soluble resins (e.g., that use organic solvents) or water-based emulsions (e.g., that use vinyl ether macromonomers containing polyoxyethylene (EO) units). The fluoroethylene vinyl ether resins may include copolymers of a hydrocarbon vinyl ether with a fluoroethylene, such as polytetrafluoroethylene (TFE) or polychlorotrifluoroethylene (CTFE), for example. It is envisioned that the fluoroethylene vinyl ether resins could be formulated with or without nano particles.

In a preferred embodiment, the layer or coating comprises UV absorbers and is UV blocking to provide UV protection to the device. Useful UV absorbers include, but are not limited to, benzotriazoles, triazines, benzophenones, and cyanoacrylates. The UV absorbers may also include inorganic UV absorbers such as nano metal oxides (e.g., zinc oxide, cerium oxide, or titanium oxide). Preferred UV absorbers may include either organic molecules or inorganic materials (e.g., ZnO and/or CeO₂) with a small particle size, e.g., less than 80 nm, which may be surface treated to reduce photocatalytic activity. The UV absorbers are at a level to provide UV protection to the substrate and all layers beneath, such that there is preferably less than 15%, more preferably less than 10% light transmission at 350 nm as measured by a Perkin Elmer Lamdba 950 UV/VIS/NIR spectrometer through the dried coating on a 5 mil SKC SH82 PET substrate. The UV absorbers could be in either layer of a multilayer weatherable coating.

The at least one layer or coating may contain other additives, such as, but not limited to, impact modifiers, nanoparticles, UV stabilizers/absorbers, plasticizers, process aids, fillers, coloring agents, pigments, antioxidants, antistatic agents, surfactants, toners, dispersing aids, cross linking agents, matting agents, adhesion promoters, and the like. These additives could be in either layer of a multilayer weatherable coating.

In the case of a photovoltaic or OLED device, the at least one weatherable layer or coating is desirably a clear coating or transparent. A clear weatherable composite system may be applied to the frontside of the device. It may also be desirable that the at least one weatherable layer or coating on the backside of the device (photovoltaic modules, in particular) is opaque or translucent white to reflect the light back into the device. Accordingly, when an opaque or translucent layer coating is desired, the layer or coating may contain a UV blocking material that blocks wavelengths less than 400 nm, such as TiO₂, ZnO, etc. An additive, such as TiO₂ pigment, may be especially preferable because TiO₂ can help to increase the total solar reflectance off the backside of the photovoltaic module and increase the module's efficiency.

The layer or coating may contain any suitable amounts of other additives, such as TiO₂, ranging from about 0.1 to 50 weight percent, 0.1 to 30 weight percent, 0.1 to 7 weight percent, or 0.1 to 1 weight percent, for example.

The thickness of the weatherable layer or coating is not especially limited and may be any suitable thickness useful to one of ordinary skill in the art. For example, the layer may range from about 1 nm to 250 μm in thickness, for example. The coating layer, preferably, is a thin coating on the order of less than 3 mil, or less than 2 mil, and most preferably less than 1 mil.

Coatings useful in the present invention may include those described in International Publication No. WO10144520, U.S. Publication No. 2011315189, and U.S. Publication No. 2010175742, each of which is incorporated herein by reference in its entirety for all purposes. These coatings may be used as the top layer or primer layer in a multilayer coating, for example.

Substrate

The weatherable composite includes a substrate that is disposed between the moisture barrier system and the at least one weatherable layer or coating. The substrates suitable for use in the present invention may include any substrate suitable for use in photovoltaic and OLED devices, for example. In a preferred embodiment, the substrate is transparent (e.g., greater than 80% light transmission, greater than 90% light transmission, etc. as measured following ASTM D1003).

Polymer substrates are especially suitable. Illustrative examples of suitable polymer substrate materials include, but are not limited to, polymeric substrates such as polyacrylates (e.g., polymethylmethacrylate), polyesters (e.g., polyethylene terephthalate), polyamides, polyimides, polycarbonates and the like. For example, a polymer substrate may be selected from the group consisting of polyethylene terephthalate (PET), polyethylene naphthalate (PEN), polybutylene terephthalate (PBT), polyvinylidene fluoride (PVDF), polymethyl methacrylate (PMMA), and combinations thereof.

In an exemplary embodiment, the substrate comprises biaxially oriented and heat set polyethylene terephthalate (PET) or polyethylene naphthalate (PEN). In one embodiment, the substrate is substantially or completely transparent. In another embodiment, the substrate is substantially or completely flexible.

Other components may also be compounded together with the substrate. For example, fillers, stabilizers, colorants, UV absorbers, plasticizers, lubricants, etc. may be added to and incorporated with the substrate or applied to the surface of the substrate based on the properties desired.

The substrate may be surface treated or chemically primed to improve adhesion to the coating and/or the barrier system. For example, corona, plasma, or flame treatments could be used and/or chemical treatments like silane, urethane, acrylic, polyethylenimine, or ethylene acrylic acid copolymer based primers could be applied to the substrate. The surface treatment or chemical primer may be the same or different on either side of the substrate depending upon the chemistry required to achieve good adhesion to the moisture barrier and weatherable layer or coating.

The substrate may be in any suitable form. For instance, the substrate may be a sheet, a film, a composite, or the like. The substrate may also be of any suitable thickness based on the intended application (e.g., a thickness of from 25 to 500 μm, preferably less than 10 mils, or less than 6 mils). The substrate may be formed by any known means, such as biaxially stretching and heat setting processes.

Weatherable Composite

The weatherable composite may be formed using any suitable equipment and techniques known to one of ordinary skill in the art. In one embodiment of the present invention, a method for forming a weatherable composite includes applying a moisture barrier system having a moisture vapor transmission rate at or below 1×10⁻² g/m²/day to a substrate, and applying at least one weatherable layer or coating to the substrate. The applying steps may be performed sequentially or simultaneously. Suitable techniques may also be used to enhance the bonding between the layers, such as corona or plasma treatments. The layers and coatings may be applied or bonded together using suitable techniques known in the art, such as curtain coating, gravure coating, roll-to-roll lamination, deposition process, etc.

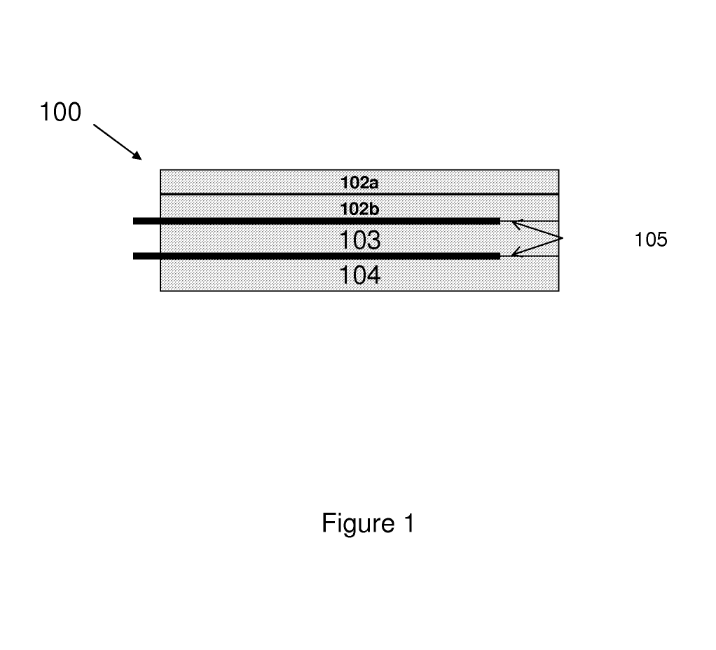

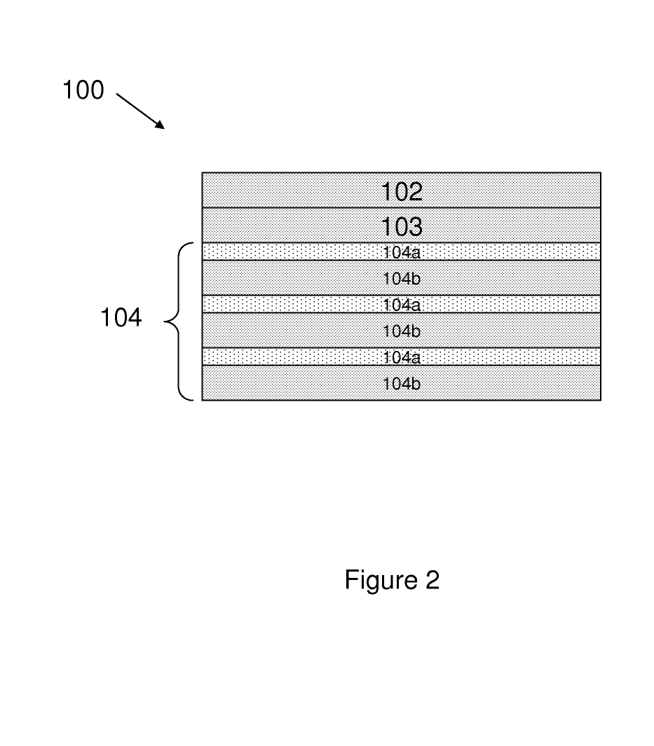

As shown in FIGS. 1 and 2, the weatherable composite 100 may include at least one weatherable layer or coating layer 102 (two weatherable layers 102a and 102b are depicted in FIG. 1), a substrate layer 103 that may include one or more surface treatments or primers 105 on one or both sides of the substrate layer 103, and a moisture barrier system 104. The moisture barrier system 104 may include alternating layers comprising inorganic layers 104a and organic layers 104b. It is noted that the layers in the figures are not to scale and are for representative purposes only.

In one embodiment of the present invention, the weatherable composite includes a moisture barrier system comprising alternating organic and inorganic layers, the moisture barrier system having a moisture vapor transmission rate at or below 1×10⁻² g/m²/day, at least one weatherable layer or coating comprising polyvinylidene fluoride; and a substrate comprising polyethylene terephthalate (PET), polyethylene naphthalate (PEN), or polybutylene terephthalate (PBT), wherein the substrate is disposed between the moisture barrier system and the at least one weatherable layer or coating.

Applications

The weatherable composite may be adhered to a device with high sensitivity to moisture such that the outermost weatherable layer or coating of the weatherable composite is exposed to the environment. The weatherable composite may also be used to block other gases as well, such as O₂. A moisture sensitive device may include a photovoltaic thin-film cell or organic light emitting diode, for example. Devices with a high sensitivity to moisture, such as CIGS, may have decreased lifetime or stop working completely if exposed to too much moisture. Due to the weatherable composite of the present invention, the devices with high sensitivity to moisture are preferably exposed to a moisture vapor transmission rate at or below 1×10⁻² g/m²/day to provide for improved performance and lifespan.

The thin-film photovoltaic cells may be made according to any known techniques, such as by depositing one or more thin layers of photovoltaic material on a substrate. The thickness range of such a layer may vary from a few nanometers to tens of micrometers. Suitable photovoltaic materials include amorphous silicon, copper-indium-gallium-selinide (CIGS) having the formula CuInₓGa₍₁₋ₓ₎Se₂, where 0<x<1, cadmium-telluride (CdTe), organic photovoltaics (OPVs), and the like. The photovoltaic thin-film cells may include other suitable materials known in the art, in addition to the photovoltaic material. For example, copper-indium-gallium-selinide may be deposited on a substrate (such as foil or glass) and may include other materials, such as a thin coating of molybdenum, zinc oxide, cadmium sulfide, etc., to form the photovoltaic cell.

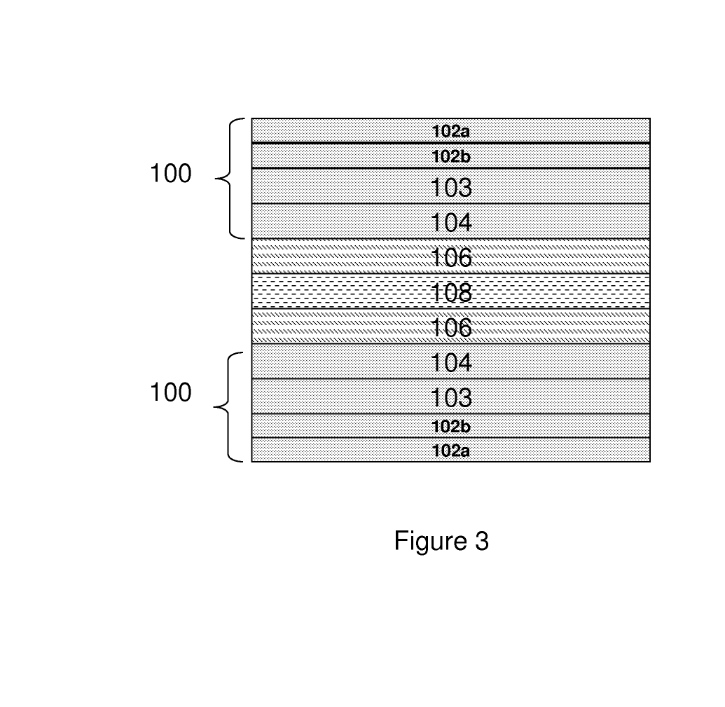

As depicted in FIG. 3, the weatherable composites 100 surround a photovoltaic device. In particular, a first weatherable composite 100 including at least one weatherable layer or coating 102 (two weatherable layers 102a and 102b are depicted), substrate layer 103, and moisture barrier system 104 is positioned on the top side and a second weatherable composite 100 including weatherable layers or coatings 102a and 102b, substrate layer 103, and moisture barrier system 104 is positioned on the under side of a solar cell 108 that is between encapsulant or adhesive layers 106. The outermost weatherable layers or coatings 102a are positioned on the outside of the device (e.g., having direct contact with the environment). Because the coating layers 102 are positioned on the front and/or backside of the device, each or both provide for UV protection, especially for layers within the composite made from PET or PEN.

Depending on the application, it may be preferred that the photovoltaic thin-film cell or organic light emitting diode is flexible. For example, a flexible thin film configuration may be used in applications, such as building integrated photovoltaic (BIPV), because they are light weight and can conform to the various shapes on the exterior of a building.

In one embodiment of the invention, the coatings of each of the weatherable composites are exposed to the environment and the first weatherable composite (top side) is transparent and the second weatherable composite (bottom side) is opaque or translucent. This configuration may be especially suitable for photovoltaic devices. In other words, a photovoltaic thin-film cell may be sandwiched between two weatherable composites as depicted in FIG. 3.

### EXAMPLES

The invention may be further illustrated by reference to the following examples.

### Example 1

### Organic Solvent Dispersion Coating—Pigmented

A dispersion coating was formulated with PVDF homopolymer resin (an emulsion polymer with Mw 450K), and an acrylic copolymer (PARALOID® B44 from Dow Chemicals). The formulation of Table 1 was mixed for 30 minutes with 125 g of 4 mm glass beads in a paint shaker. The coating was applied with an 8 path wet film applicator with a 5 mil gap to a primed PET film (SKC SH-82) of 5 mils thickness. The coating was allowed to flash at room temperature for 1 minute followed by baking at 170° C. (338° F.) for 1 minute. A smooth white coating resulted. This coating was tested by humidity exposure at 85° C. /85% RH for 1000 hours followed by cross hatch adhesion test (ASTM D3359-09). This coating successfully passed the adhesion test with less than 20% loss of coating in the test area.

TABLE 1

| Solvent Dispersion Example #1 | Amount (g) |
|---|---|
| PVDF homopolymer resin | 20.5 |
| Acrylic copolymer | 8.8 |
| Toluene | 14.0 |
| Methylisobutylketone | 41.8 |
| Ti Pure ® R-960 - TiO₂ (DuPont) | 15.8 |

This coating was also tested by accelerated weathering in a QUV B test unit. After 5000 hours of exposure, the coating still had >60% gloss retention, indicating good weathering. This pigmented coating is suitable for the outer weatherable protection layer in barrier systems used on the backside of solar modules.

### Example 2

### Organic Dispersion Coating—Unpigmented With Nano-Cerium Oxide additive

A dispersion coating is formulated with PVDF homopolymer resin (an emulsion polymer with Mw 450K), and an acrylic copolymer (PARALOID® B44 from Dow Chemicals). The formulation of Table 2 is mixed for 30 minutes with 125 g of 4 mm glass beads in a paint shaker. The coating was applied to 5 mil thick SKC SH82 PET using an 8 path wet film applicator with an 8 mil gap. The coating was allowed to flash at room temperature for 1 minute followed by baking at 170° C. (338° F.) for 1 minute. A smooth hazy coating was made.

TABLE 2

| Solvent Dispersion Example #2 | Amount (g) |
|---|---|
| PVDF homopolymer resin | 20.5 |
| Acrylic copolymer | 8.8 |
| Toluene | 14.0 |
| Methylisobutylketone | 41.8 |
| Nanobyk ® 3810 | 2.0 |

This unpigmented coating/PET sample had a total transmission of 90.3% and haze of 23.8% as measured following the methods described in ASTM D1003. The coating provides UV protection to the PET substrate as the light transmission percentage of the unpigmented coating/PET sample was measured to be 8% at 350 nm using a Perkin Elmer Lamdba 950 UV/VIS/NIR spectrometer. This unpgimented, transparent coating is suitable for the outer weatherable protection layer in barrier systems used on the frontside or backside of solar modules.

### Example 3

### Aqueous Dispersion Coating with Crosslinking—Pigmented

A PVDF-acrylic hybrid dispersion was prepared as follows: A PVDF copolymer fluoropolymer latex: (resin composition is of 75/25 wt % VF2/HFP, latex particle size by light scattering 140 nm, 41 wt % solids) was used as received. This dispersion had a first heat DSC enthalpy of melting of 17.5 Joules/gram on dry polymer, with a principal crystalline melting peak of 103° C., VAZO®-67 (Dupont), POLYSTEP B7 ammonium lauryl sulfate (STEPAN®, 30 wt % aqueous solution) are used as received. Methyl methacrylate, hydroxyethyl methacrylate, methacrylic acid, and ethyl acrylate from Aldrich are used as received.

In a separate vessel, a monomer mixture—(monomer mixture A)—was prepared from methyl methacrylate (210 g), hydroxyethyl methacrylate (18 g), ethyl acrylate (72 g) and isooctylmercaptopropionate (0.5 g).

In another separate vessel, a monomer mixture—(monomer mixture B)—was prepared from methyl methacrylate (87 g), hydroxyethyl methacrylate (102 g), ethyl acrylate (102 g), methacrylic acid (9 g), and isooctylmercaptopropionate (0.5 g). An initiator solution is prepared from 3.8 g VAZO®-67 (DuPont) and tripropylene glycol monomethyl ether (18.7 g).

1463 g of the fluoropolymer latex was charged into a kettle equipped with a condenser, high purity argon and monomer inlets and a mechanical stirrer. 275 g water and 15 g POLYSTEP® B7 are added. After the reactor and its initial contents were flushed and purged for 10 minutes, 60 g of monomer mixture A was introduced into the reactor at a rate of 600 g /hour. Then the initiator solution was added. The reactor and its contents were stirred under argon for 30 minutes, while heating to 75° C. Then the remaining portion of monomer mixture A was added at a rate of 204 g/hour. After 30 minutes, monomer mixture B was fed at a rate of 240 g/hour. When all the monomer mixture was added, the residual monomer was consumed by maintaining the reaction temperature at 75° C. for an additional 30 minutes. Then 0.7 g of a mixture of t-butyl hydroperoxide and sodium formaldehyde sulfoxylate were added to the reactor, and the reactor was then maintained at 75° C. for an additional 30 minutes. The reaction mixture was then cooled to ambient temperature, vented and the dispersion produced by the reaction filtered through a cheese cloth. The final solids content of the dispersion was measured by gravimetric method and was of 49.5 weight percent. The dispersion was neutralized with aqueous ammonia to a pH of about 7.8. The minimum film formation temperature of the dispersion was 15° C.

A 2-component white aqueous coating was formulated based upon this dispersion, using the following formulation:

| | Quantity, grams |
|---|---|
| Pigment concentrate 1 | |
| Water | 149.3 |
| DISPER BYK ® 190 (dispersing agent)- Altana | 13.8 |
| Ammonia | 0.3 |
| TEGOFOAMEX ® 810 (Evonik) | 1.3 |
| TRITON CF ®-10 (Dow Chemical) | 5.5 |
| TIPURE ® R-960 rutile TiO2 (DuPont) | 552.1 |
| A component: | |
| Neutralized PVDF-acrylic hybrid dispersion from | 99.0 |
| above | |
| BYK ® 346 (Altana) | 0.1 |
| Dipropylene glycol dimethyl ether | 3.0 |
| TiO₂ Pigment concentrate 1 | 58 |
| Final formulation, mixed on day of application: | |
| A component from above | 75 |
| Water | 5 |
| BAYHYDUR ® XP-2655 (Bayer Material Sciences) | 5 |

The pigment concentrate 1 was prepared using a Cowles high speed mixer where it was run at 2000 rpm for 15 minutes and then 4000 rpm for 30 minutes. The A component and the final formulation were each mixed using a low speed mixing stirrer at 500 rpm for 10 minutes.

The white aqueous coating was applied to the same pre-treated PET as in Example 1, using an 8 path wet film applicator with a 5 mil gap to a dry coating thickness of approximately 1 mil. The sample was allowed to flash at room temperature for 10 minutes and then oven baked for 30 minutes at 80° C. The sample was subjected to 85° C/85% relative humidity damp heat testing for 1000 hours and tested for coating adhesion as in Example 1. There was excellent adhesion as noted by a 100% retention of squares on the substrate for the sample. This pigmented coating is suitable for the outer weatherable protection layer in barrier systems used on the backside of solar modules.

### Example 4

### Aqueous Dispersion Coating with Crosslinking, Unpigmented Nano Absorber (Nano-Zinc) (Prophetic)

A PVDF-acrylic IPN dispersion is prepared as follows and in accordance with Example 3.

A 2-component clear aqueous coating is formulated based upon this dispersion, using the following formulation:

| | Quantity, grams |
|---|---|
| A component: | |
| Neutralized PVDF-acrylic hybrid dispersion from | 99.0 |
| above | |
| BYK ® 346 (Altana) | 0.1 |
| Dipropylene glycol dimethyl ether | 3.0 |
| ZANO 20 PLUS ® (Umicore) | 2.0 |
| Final formulation, mixed on day of application: | |
| A component from above | 75 |
| Water | 5 |
| BAYHYDUR ® XP-2655 (Bayer Material Sciences) | 5 |

The A component and the final formulation is each mixed using a low speed mixing stirrer at 500 rpm for 10 minutes.

The clear aqueous coating is applied to the same pre-treated PET as in Example 1 using an 8 path wet film applicator with a 5 mil gap to a dry coating thickness of approximately 1 mil. The sample is allowed to flash at room temperature for 10 minutes and then oven baked for 30 minutes at 80° C. The samples are subjected to 85° C/85% relative humidity damp heat testing 1000 hours and tested for coating adhesion as in Example 1. Excellent adhesion is likely as noted by a 100% retention of squares on the substrate. Accelerated weathering may be carried out in QUV A for 5000 hours, which should show gloss retention >60%, showing superior weatherability of this coating.

This clear, weatherable coating is suitable for the outer weatherable protection layer in barrier systems used on the frontside or backside of solar modules.

### Example 5

### Waterborne Coating, Unpigmented w/Nano Cerium Oxide (Prophetic)

The formulation is mixed using a low speed mixing stirrer at 500 rpm for 10 minutes. The clear aqueous coating is applied to the same pre-treated PET as in Example 1, using an 8 path wet film applicator with a 5 mil gap to a dry coating thickness of approximately 1 mil. The sample is allowed to flash at room temperature for 10 minutes and then oven baked for 30 minutes at 80° C. Accelerated weathering may be carried out in QUV A for 5000 hrs. It is expected that gloss retention is >60%, showing superior weatherability of this coating.

| | Amount |
|---|---|
| Ingredients | (g) |
| KYNAR AQUATEC ® ARC | 45.8 |
| Diethylene glycol monobutyl ether (DB) | 3.3 |
| ACRYSOL ® RM-825 | 0.22 |
| BYK ®-346 (Altana) | 0.08 |
| UMICORE NANOGRAIN ® Nano CeO₂ - W139 (30% solids) | 1.57 |
| Total | 50.97 |

This clear, weatherable coating is suitable for the outer weatherable protection layer in barrier systems used on the frontside or backside of solar modules.

### Example 6

### Waterborne Coating, Unpigmented w/Nano Zinc Oxide (Prophetic)

The formulation is mixed using a low speed mixing stirrer at 500 rpm for 10 minutes. The clear aqueous coating is applied to the same pre-treated PET as in Example 1, using an 8 path wet film applicator with a 5 mil gap to a dry coating thickness of approximately 1 mil. The sample is allowed to flash at room temperature for 10 minutes and then oven baked for 30 minutes at 80° C. Accelerated weathering may be carried out in QUV A for 5000 hrs. It is expected that gloss retention is >60%, showing superior weatherability of this coating.

| Ingredients | Amount (g) |
|---|---|
| KYNAR AQUATEC ® ARC | 45.8 |
| Diethylene glycol monobutyl ether (DB) | 3.3 |
| ACRYSOL ® RM-825 | 0.22 |
| \BYK ®-346 (Altana) | 0.08 |
| UMICORE ZANO ® dispersion ZnO - W062 (50% solids) | 0.86 |
| Total | 50.26 |

This clear, weatherable coating is suitable for the outer weatherable protection layer in barrier systems used on the frontside or backside of solar modules.

### Example 7

### Waterborne Coating, Unpigmented w/Organic UV Absorber

The formulation is mixed using a low speed mixing stirrer at 500 rpm for 10 minutes. The clear aqueous coating was applied to 5 mil thick Kolon CD 105 PET, an 8 path wet film applicator with a 5 mil gap to a dry coating thickness of approximately 1 mil. The samples were allowed to flash at room temperature for 10 minutes and then oven baked for 30 minutes at 80° C.

| Ingredients | Amount (g) |
|---|---|
| KYNAR AQUATEC ® ARC | 130 |
| Dipropylene glycol methyl ether | 8.3 |
| Aqueous ammonia (28%) | 0.4 |
| BYK ®-346 (Altana) | 0.13 |
| COAPUR XS-52:water (1:3) | 5.2 |
| TINUVIN ® 1130 (BASF) | 1.9 |
| Total | 145.9 |

The resulting dry coating on PET had very good transparency. This unpigmented coating/PET sample had a total transmission of 92.5% and haze of 2.8% as measured following the methods described in ASTM D1003. The coating provides UV protection to the PET substrate as the light transmission percentage of the unpigmented coating/PET sample was measured to be <0.5% at 350 nm using a Perkin Elmer Lamdba 950 UV/VIS/NIR spectrometer. This clear, weatherable coating is suitable for the outer weatherable protection layer in barrier systems used on the frontside or backside of solar modules.

### Example 8

### Aqueous Dispersion Coating with Crosslinking—Unpigmented with Organic UV Absorber

An aqueous PVDF-acrylic hybrid dispersion was prepared according to the method of Example 3, but with the following variations: a) in monomer mixtures A and B, hydroxypropyl methacrylate was used in place of hydroxyethyl methacrylate; and b) the total amount of acrylic monomer was reduced to give a final dispersion with a composition of approximately 70 wt % PVDF copolymer: 30 wt % acrylic copolymer on total polymer solids. The wt % solids of the hybrid dispersion was 44 wt % and the minimum film formation temperature of the dispersion was 17° C.

A 2-component aqueous clear coating was formulated based upon this dispersion, using the following formulation:

| | Reagents | g |
|---|---|---|
| A Component: | PVDF-Acrylic Hybrid dispersion | 300 |
| | BYK ® 346 (Altana) | 0.6 |
| | TINUVIN ® 1130 (BASF) | 4.0 |
| | Dipropylene glycol dimethyl ether | 5.0 |
| | A Component total | 309.6 |
| B Component: | Bayhydur XP-2655 (Bayer) | 8.4 |
| | Dipropylene glycol dimethyl ether | 2.1 |
| | B Component total | 10.5 |
| Add component B to | Formulation total | 320.1 |
| Component A with good | | |
| mixing. Formulation potlife | | |
| approx. 4 hours | | |

The resulting formulation was applied using a draw down square with a 10 mil gap on 5 mil thick KOLON CD 105 PET film, allowed to flash at room temperature for 1 hour, and baked at 70 C for 10 minutes. The resulting coating had very good transparency. The total transmission percentage of the dried coating/PET sample was 92.6%, and the haze was 4.0%, as measured following ASTM D 1003. The coating provides UV protection to the PET substrate as the light transmission percentage of the unpigmented coating/PET sample was measured to be <0.5% at 350 nm using a Perkin Elmer Lamdba 950 UV/VIS/NIR spectrometer.

This clear, weatherable coating is suitable for the outer weatherable protection layer in barrier systems used on the frontside or backside of solar modules.

### Example 9

### Organic Dispersion Coating—Unpigmented with Nano-Zinc Additive—on a Barrier (BARIX™) System (Prophetic)

A BARIX™ Barrier Film (obtainable from Vitex Systems with offices in San Jose, Calif.) is selected having layers of thin polymer that are deposited alternatively with thin metal oxide barrier layers, which is applied to a base film of PET or PEN.

The unpigmented coating of Example 8 is applied to the base PET or PEN film of the Barix™ Barrier Film. The coating is allowed to flash at room temperature for 1-10 minutes followed by baking at 120° C. (338° F.) for 1-5 minutes. This transparent weatherable composite is suitable for use on the frontside or backside of solar modules.

### Example 10

### Solvent-Based FEVE Coating, Unpigmented w/Organic UV Absorber (Prophetic)

The LUMIFLON® LF200F FEVE resin is dissolved in an equal weight of MiBK to make a 50 wt % solution. The other formulation ingredients, except for the hardener, are then added using a low speed mixing stirrer at 500 rpm for 10 minutes. At the point of use, the hardener is than added. The resulting clear coating is applied to the same pre-treated PET as in Example 1, using a knife-over roll or gravure coating apparatus to a dry coating thickness of approximately 20 microns. The samples are then baked in a multi-zone force-air oven with a final zone temperature of 80° C., and a residence time of 20 minutes.

| | Amount |
|---|---|
| Ingredients | (g) |
| LUMIFLON ® LF200F (FEVE resin-Asahi Glass) | 35.4 |
| Methyl isobutyl ketone (MiBK) | 35.4 |
| Cyclohexanone | 10.0 |
| BYK ®-333 (Altana) | 0.05 |
| TINUVIN ® 928 (BASF) | 3.5 |
| Hardener: DESMODUR ® Z4470SN (Bayer Material Sciences) | 11.0 |
| Total | 94.85 |

This clear, weatherable coating is suitable for the outer weatherable protection layer in barrier systems used on the frontside or backside of solar modules.

While preferred embodiments of the invention have been shown and described herein, it will be understood that such embodiments are provided by way of example only. Numerous variations, changes and substitutions will occur to those skilled in the art without departing from the spirit of the invention. Accordingly, it is intended that the appended claims cover all such variations as fall within the spirit and scope of the invention.

1. A weatherable composite comprising:
a moisture barrier system having a moisture vapor transmission rate at or below 1×10⁻² g/m²/day;
at least one weatherable layer or coating; and
a substrate, wherein the substrate is disposed between the moisture barrier system and the at least one weatherable layer or coating.

2. The weatherable composite according to claim 1, wherein the moisture barrier system comprises alternating layers of at least one organic film and at least one inorganic film.

3. The weatherable composite according to claim 2, wherein the inorganic film comprises at least one metal oxide.

4. The weatherable composite according to claim 3, wherein the at least one metal oxide is selected from the group consisting of silicon oxides, tin oxides, aluminum oxides, zinc oxides, and mixtures thereof.

5. The weatherable composite according to claim 2, wherein the organic film comprises a polymer selected from the group consisting of polyesters, polyacrylates, polyimides, and polycarbonates.

6. The weatherable composite according to claim 1, wherein the substrate comprises polyethylene terephthalate (PET), polyethylene naphthalate (PEN), or polybutylene terephthalate (PBT).

7. The weatherable composite according to claim 1, wherein the at least one weatherable layer or coating comprises at least one fluoropolymer.

8. The weatherable composite according to claim 7, wherein the at least one fluoropolymer comprises a polyvinylidene fluoride homopolymer or copolymer.

9. The weatherable composite according to claim 7, wherein the at least one weatherable layer or coating comprises a non-functionalized acrylic.

10. The weatherable composite according to claim 1, wherein the at least one weatherable coating or layer is selected from the group consisting of fluoropolymers, acrylics, silicone-acrylics, silicone-polyesters, and mixtures thereof

11. The weatherable composite according to claim 1, wherein the at least one weatherable layer or coating comprises one or more UV absorbers.

12. The weatherable composite according to claim 1, wherein the at least one weatherable layer or coating is transparent.

13. The weatherable composite according to claim 1, wherein the at least one weatherable layer or coating is opaque or translucent.

14. The weatherable composite according to claim 1, wherein the weatherable composite is adhered to a photovoltaic thin-film cell or organic light emitting diode such that the at least one weatherable layer or coating is exposed to the environment.

15. The weatherable composite according to claim 14, wherein the photovoltaic thin-film cell or organic light emitting diode is selected from the group consisting of amorphous silicon, copper-indium-gallium-selinide (CIGS), cadmium-telluride (CdTe), and organic photovoltaics (OPVs).

16. The weatherable composite according to claim 14, wherein the photovoltaic thin-film cell or organic light emitting diode is flexible.

17. The weatherable composite according to claim 1, wherein the moisture barrier system has a moisture vapor transmission rate at or below 1×10⁻⁵ g/m²/day

18. A photovoltaic thin-film cell sandwiched between two weatherable composites according to claim 1, wherein the weatherable layers or coatings of each of the weatherable composites are exposed to the environment, wherein the first weatherable composite is transparent and the second weatherable composite is opaque.

19. A weatherable composite comprising:
a moisture barrier system comprising alternating layers of at least one organic layer and at least one inorganic layer, the moisture barrier system having a moisture vapor transmission rate at or below 1×10⁻² g/m²/day;
at least one weatherable layer or coating comprising polyvinylidene fluoride; and
a substrate comprising polyethylene terephthalate (PET), polyethylene naphtholate (PEN), or polybutylene terephthalate (PBT), wherein the substrate is disposed between the moisture barrier system and the at least one weatherable layer or coating.

20. The weatherable composite according to claim 19 further comprising a photovoltaic thin-film cell adhered to the moisture barrier system, wherein the photovoltaic thin-film cell comprises copper-indium-gallium-selinide (CIGS) or an organic photovoltaic (OPV).

21. The weatherable composite according to claim 19, wherein the weatherable composite is transparent.

22. A photovoltaic thin-film cell comprising copper-indium-gallium-selinide (CIGS), wherein the photovoltaic thin-film cell is sandwiched between two weatherable composites according to claim 19, such that the weatherable layers or coatings comprising polyvinylidene fluoride are exposed to the environment.

23. A method for forming a weatherable composite, the method comprising:
applying a moisture barrier system having a moisture vapor transmission rate at or below 1×10⁻² to a substrate; and
applying at least one weatherable layer or coating to the substrate.
